(19) United States
(12) Patent Application Publication
(10) Pub. No.: US 2012/0186644 A1
(43) Pub. Date: Jul. 26, 2012

(54) FLEXIBLE ELECTRODES AND PREPARATION METHOD THEREOF, AND FLEXIBLE DYE-SENSITIZED SOLAR CELLS USING THE SAME

(75) Inventors: Min Jae KO, Seoul (KR); Kyungkon KIM, Seoul (KR); Won Mok KIM, Seoul (KR); Seung Hee HAN, Seoul (KR); Hong Gon KIM, Seoul (KR); Doh-Kwon LEE, Seoul (KR); Ki Cheon YOO, Seoul (KR); Jin-soo KIM, Seoul (KR)

(73) Assignee: KOREA INSTITUTE OF SCIENCE AND TECHNOLOGY, Seoul (KR)

(21) Appl. No.: 13/191,692

(22) Filed: Jul. 27, 2011

(30) Foreign Application Priority Data
Jan. 20, 2011 (KR) 10-2011-0005946

(51) Int. Cl. H01L 31/0224; B82Y 40/00

(52) U.S. Cl. 136/256; 438/98; 977/773; 257/E31.124

(57) ABSTRACT

The present invention relates to a flexible photoelectrode and a manufacturing method thereof, and a dye-sensitized solar cell using the same. More particularly, the present invention relates to a flexible photoelectrode capable of forming a semiconductor electrode with excellent photoelectric conversion efficiency on a plastic substrate at low temperatures in a simple and stable manner, in which it is prepared by forming a nanocrystalline metal oxide layer calcined at high temperature on a high temperature resistant substrate, and transferring it to a flexible transparent substrate by a transfer method using an HF solution, and a flexible dye-sensitized solar cell comprising the same.

### CROSS-REFERENCE TO RELATED APPLICATION

This application claims priority to and the benefit under 35 U.S.C. §119(a) of a Korean patent application No. 10-2011-0005946 filed on Jan. 20, 2011, the entire disclosure of which is incorporated herein by reference for all purposes.

### BACKGROUND OF THE INVENTION

(a) Field of the Invention

The present invention relates to a method for manufacturing a flexible photoelectrode comprising a flexible transparent substrate, a flexible photoelectrode manufactured thereby, and a flexible dye-sensitized solar cell using the same.

(b) Description of the Related Art

A dye-sensitized solar cell (dye-sensitized photovoltaic cell) is a representative photoelectrochemical solar cell which has been reported by Gratzel et al. (Switzerland) in 1991, and typically consists of a photosensitive dye absorbing visible light, metal oxide nanoparticles having a wide band gap energy, a Pt-based counter electrode as a catalytic electrode, and an electrolyte sandwiched therebetween. The dye-sensitized solar cell possesses advantages of low production costs compared to the traditional silicon-based solar cells or chemical semiconductor-based solar cells, and high efficiency compared to organic material-based solar cells. The dye-sensitized solar cell is also advantageous in that it is eco-friendly and can be fabricated in a transparent form.

In particular, a flexible dye-sensitized solar cell, employing a flexible semiconductor electrode, has attracted significant attention owing to its ability to be used as part of an auto-chargeable battery for mobile phones and next-generation personal computers (PCs) such as wearable PCs, and owing to its ability to be mounted on numerous items such as clothes, caps, automobile glass, buildings or the like.

However, flexible semiconductor electrodes should be generally manufactured at 150° C. or less, because plastic substrates required for the fabrication of flexible semiconductor electrodes are easily distorted at higher temperatures. That is, it is impossible to heat-treat the flexible plastic substrates at high temperature, and thus metal oxide such as TiO₂ should be calcined at low temperature. Upon low-temperature calcination, however, photoelectron transport ability is remarkably reduced due to the lack of interconnection between TiO₂ particles. In the conventional methods of manufacturing a semiconductor electrode employing the plastic substrate, a paste for low-temperature calcination is printed on the substrate and dried at 100° C. or lower, or a semiconductor layer is formed on a non-transparent metal foil. However, such methods suffer from problems of low photoelectric conversion efficiency of solar cells and poor film stability.

### SUMMARY OF THE INVENTION

In order to solve the above described problems occurring in the prior art, an object of the present invention is to provide a method for manufacturing a flexible photoelectrode, in which a semiconductor electrode can be formed on a flexible plastic substrate with excellent interconnectivity by a transfer method at low temperatures in a simple and stable manner.

Another object of the present invention is to provide a flexible photoelectrode manufactured by the method.

Still another object of the present invention is to provide a flexible dye-sensitized solar cell having a highly stable semiconductor film layer and high photoelectric efficiency by using the flexible photoelectrode as a semiconductor electrode.

### BRIEF DESCRIPTION OF THE DRAWINGS

FIG. 1 is a schematic view illustrating a method for manufacturing a flexible photoelectrode and a method for manufacturing a dye-sensitized solar cell comprising the photoelectrode according to the present invention;

FIG. 2 is a schematic view illustrating a transfer method using an HF solution of the present invention;

FIG. 3 is a cross sectional view of the flexible dye-sensitized solar cell according to the present invention;

FIG. 4 shows a comparison between the operating principle of a dye-sensitized solar cell using the conventional conductive glass substrate (a) and that of the solar cell of the present invention (b);

FIG. 5 is a cross sectional view of the conventional flexible dye-sensitized solar cell, based on low temperature calcination; and

FIG. 6 is a graph showing a comparison in current-voltage curves between the dye-sensitized solar cells according to Example 1 and Comparative Example 1 of the present invention.

### EXPLANATIONS OF REFERENCE NUMERALS

12: flexible substrate
13: conductive film
15: porous layer including dye-adsorbed metal oxide nanoparticles
17: catalyst layer
10: photoelectrode
20: counter electrode
30: electrolyte
40: polymer adhesive layer
101: high temperature resistant substrate
102: flexible transparent substrate
103: porous layer including metal oxide nanoparticles
104: adhesive layer
105: conductive non-metal film
106: porous layer including dye-adsorbed metal oxide nanoparticles
107: conductive film
108: catalyst layer
100: photoelectrode
110: counter electrode
120: electrolyte
130: polymer adhesive layer

### DETAILED DESCRIPTION OF THE EMBODIMENTS

The present invention provides a method for manufacturing a flexible photoelectrode, comprising the steps of:
(a) preparing a first substrate that includes a high temperature resistant substrate, a porous layer including metal oxide nanoparticles, an adhesive layer and a flexible transparent substrate;
(b) separating the high temperature resistant substrate from the first substrate by a transfer method so as to prepare a second substrate that includes the flexible transparent substrate, and the adhesive layer and the porous layer disposed on the flexible transparent substrate;
(c) forming a conductive non-metal film on the side of the porous layer and the adhesive layer and on the top of flexible transparent substrate of the second substrate so as to prepare a third substrate including the flexible transparent substrate, and the adhesive layer, the porous layer and the conductive non-metal film that are formed on the flexible transparent substrate; and
(d) adsorbing a dye on the surface of the porous layer of the third substrate.

Further, the present invention provides a flexible photoelectrode for a dye-sensitized solar cell manufactured by the above method, comprising a flexible transparent substrate, an adhesive layer formed on one side of the flexible transparent substrate, a porous layer including dye-adsorbed metal oxide nanoparticles that is formed on the adhesive layer, and a conductive non-metal film that is directly formed on the top and the side of the porous layer and directly formed on the side of the adhesive layer and on the top of the flexible transparent substrate where the adhesive layer is not formed.

Further, the present invention provides a flexible dye-sensitized solar cell, comprising the flexible photoelectrode, a counter electrode disposed to face the photoelectrode with a predetermined space, and an electrolyte charged between the photoelectrode and the counter electrode.

Hereinafter, the present invention will be described in detail.

As described above, the conventional methods of manufacturing a semiconductor electrode having a general flexible substrate suffer from problems of low photoelectric conversion efficiency of solar cells and poor film stability.

Therefore, the present invention is intended to provide a method applicable to mobile phones and next-generation PCs such as wearable PCs, in which a nanocrystalline metal oxide layer calcined at high temperature is included to improve photoelectric conversion efficiency and also to provide flexibility.

The method of the present invention comprises a method of applying a nanocrystalline oxide layer, which is formed on a high temperature-calcinable high temperature-resistant substrate, to a flexible transparent substrate by a transfer method. Further, the present invention is characterized by providing a flexible dye-sensitized solar cell, comprising a film that is calcined at high temperature using the high temperature resistant substrate.

That is, the present invention provides a method for forming the nanocrystalline oxide layer on the high temperature resistant substrate by calcination at high temperature, applying the flexible transparent substrate thereon, separating the nanocrystalline oxide layer from the glass substrate by a transfer method, and transferring the nanocrystalline oxide layer to the flexible transparent substrate so as to form a back electrode on the flexible transparent substrate. Further, the present invention provides a dye-sensitized solar cell manufactured using the back electrode. According to the present invention, as long as the nanocrystalline oxide layer is transferred from the high temperature resistant substrate to the flexible substrate, any transfer method can be applied without limitation. Preferably, the transfer method is performed according to the method described in the present invention.

Preferred embodiments of the present invention will be described below with reference to the accompanying drawings, in order to enable those skilled in the art to practice the invention. Although the preferred embodiments of the present invention are disclosed for illustrative purposes, those skilled in the art will appreciate that various modifications are possible, without departing from the concept and scope of the invention. In the drawings, like reference numerals refer to identical or substantially similar components.

It will be understood that when an element is referred to as being “on” or “on the top of” another element, it can be directly on the other element or intervening elements may be present therebetween. In contrast, when an element is referred to as being “directly on” another element, there are no intervening elements present.

Further, although the terms first, second, third, etc may be used herein to describe various elements, components, regions, layers and/or sections, these elements, components, regions, layers and/or sections should not be limited by these terms. These terms are only used to distinguish one element, component, region, layer or section from another element, component, region, layer or section.

The terminology used herein is for the purpose of describing particular embodiments only and is not intended to be limiting of the invention. As used herein, the terms “comprise”, “comprises”, and “comprising” specify the presence of stated features, regions, integers, steps, operations, elements, and/or components, but do not preclude the presence and/or addition of other features, regions, integers, steps, operations, elements, and/or components.

As used herein, the term “nano” means nano-scale, and may comprise micro-scale. Further, the term “nanoparticle”, as used herein, comprises various types of nano-scale particles.

As used herein, the term “flexible photoelectrode” means a “semiconductor electrode having a flexible substrate”, which can be used in a dye-sensitized solar cell. Further, as used herein, the term “porous layer including metal oxide nanoparticles” means a nanocrystalline oxide layer. In this connection, the “nanocrystalline oxide layer” may be a porous layer including dye-adsorbed metal oxide nanoparticles, if necessary.

As used herein, the term “high temperature resistant substrate” means a substrate that is able to endure high temperature calcination for the formation of the porous layer including metal oxide nanoparticles and is used for the transfer of the porous layer. Any type of substrate may be employed without limitation, as long as it is able to endure high temperature calcination. That is, since the high temperature resistant substrate functions to temporarily provide a template for high temperature calcination upon formation of the porous layer, it has only to endure high temperature during calcination. In addition, the high temperature resistant substrate is only provided as a bottom board for the transfer of the porous layer. Therefore, it is not required to be transparent and to have a conductive film. For example, the high temperature resistant substrate may be a glass substrate, a ceramic substrate, a metal substrate or the like which is calcinable at the temperature of 300 to 600° C. Preferably, the high temperature resistant substrate may be a glass substrate having no conductive film.

Meanwhile, according to one preferred embodiment of the present invention, a method for manufacturing a flexible photoelectrode is provided, in which the method comprises the steps of:
(a) preparing a first substrate that includes a high temperature resistant substrate, a porous layer including metal oxide nanoparticles, an adhesive layer and a flexible transparent substrate;
(b) separating the high temperature resistant substrate from the first substrate by a transfer method so as to prepare a second substrate that includes the flexible transparent substrate, and the adhesive layer and the porous layer disposed on the flexible transparent substrate;
(c) forming a conductive non-metal film on the side of the porous layer and the adhesive layer and on the top of flexible transparent substrate of the second substrate so as to prepare a third substrate including the flexible transparent substrate, and the adhesive layer, the porous layer and the conductive non-metal film that are formed on the flexible transparent substrate; and
(d) adsorbing a dye on the surface of the porous layer of the third substrate.

In the present invention, as described in the above method, the metal oxide nanoparticle layer such as TiO₂, which is previously heat-treated on the different high temperature resistant substrate and thus shows an excellent inter-particle bonding strength, is formed and then transferred to a plastic substrate, thereby forming a back electrode having excellent photoelectron transport ability on the flexible transparent substrate.

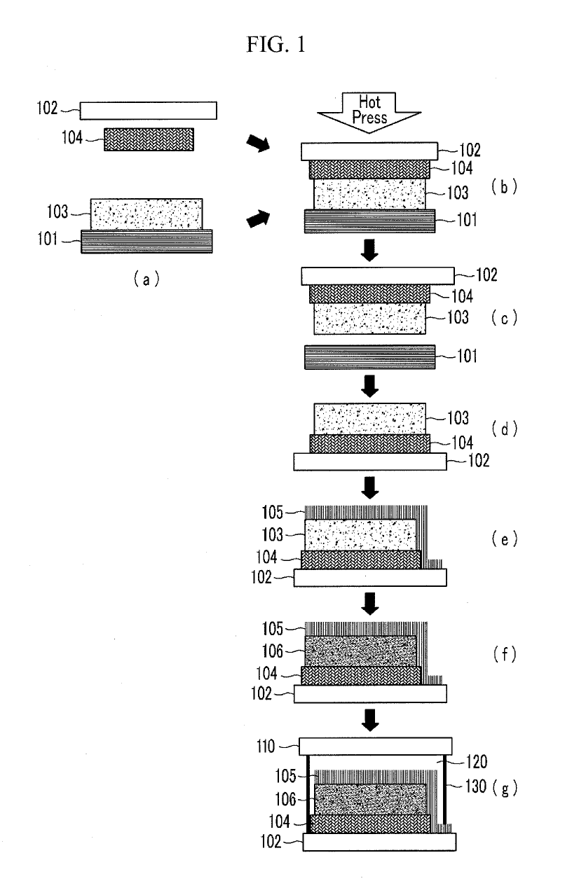

The method for manufacturing a flexible photoelectrode of the present invention is preferably performed according to the method shown in FIG. 1. FIG. 1 is a schematic view illustrating a method for manufacturing a flexible photoelectrode and a method for manufacturing a dye-sensitized solar cell comprising the photoelectrode according to the present invention.

With reference to FIG. 1, in the present invention, a high temperature resistant substrate 101 such as glass substrate is prepared, and a porous layer including metal oxide nanoparticles 103 is formed thereon by high temperature calcination ((a) of FIG. 1).

Thereafter, in the present invention, an adhesive layer 104 and a flexible transparent substrate 102 are sequentially disposed on the porous layer 103, and then the hot press is performed to prepare a first substrate that includes the high temperature resistant substrate 101, the porous layer including metal oxide nanoparticles 103, the adhesive layer 104 and the flexible transparent substrate 102 ((b) of FIG. 1).

Subsequently, the high temperature resistant substrate 101 is separated from the first substrate by a transfer method using an HF solution, so as to prepare a second substrate that includes the flexible transparent substrate 102, and the adhesive layer 104 and the porous layer 103 disposed on the flexible transparent substrate ((c) and (d) of FIG. 1).

Further, in the present invention, a conductive non-metal film 105 is formed on the porous layer 103, the adhesive layer 104 and the flexible transparent substrate 102 of the second substrate, so as to prepare a third substrate including the flexible transparent substrate 102, and the adhesive layer 104, the porous layer 103 and the conductive non-metal film 105 that are formed on the flexible transparent substrate ((e) of FIG. 1).

Further, in the present invention, a porous layer 106 including dye-adsorbed metal oxide nanoparticles is formed by adsorbing a dye on the surface of the porous layer 103 of the third substrate, so as to prepare a flexible photoelectrode ((f) of FIG. 1).

Finally, in the present invention, a counter electrode 110 is disposed to face the conductive non-metal film 105 of the flexible photoelectrode with a predetermined space, and then an electrolyte 120 is injected therebetween and sealed using a polymer adhesive 130, so as to prepare a flexible dye-sensitized solar cell ((g) of FIG. 1).

In this regard, the step of preparing a first substrate may comprise the steps of forming the porous layer including metal oxide nanoparticles on one side of the high temperature resistant substrate, and then sequentially disposing the adhesive layer and the flexible transparent substrate on the porous layer including metal oxide nanoparticles, followed by hot press of the substrate. In the present invention, that is, a transparent thermal fusion polymer film and the flexible transparent substrate are disposed on the porous layer, and then heat and pressure are applied to prepare a first substrate that includes high temperature resistant substrate-porous layer-adhesive layer-flexible transparent substrate in this order.

In this regard, the porous layer may be formed by coating one side of the high temperature resistant substrate with a paste containing metal oxide nanoparticles, a binder and a solvent and by heat-treatment at a temperature of 450 to 500° C. for 1-2 hrs.

The paste may be prepared by the method well known in the art, and the method is not particularly limited. For example, the paste may be prepared by mixing the metal oxide nanoparticles with a solvent to form a colloidal solution with a viscosity of 5×10⁴ to 5×10⁵ cps comprising the metal oxide dispersed therein, and adding a binder resin thereto, and then removing the solvent using an evaporator. In addition, the mixing ratio and type of the metal oxide nanoparticles, the binder resin and the solvent are not particularly limited, and the method well known in the art may be used. For example, the binder resin may be polyethylene glycol, polyethylene oxide, polyvinyl alcohol, polyvinyl pyrrolidone, ethyl cellulose or the like. In addition, the solvent may be ethanol, methanol, terpineol, lauric acid or the like.

Preferably, the metal oxide nanoparticles in the paste have a particle size of 10 to 100 nm. The metal oxide nanoparticles may be one or more selected from the group consisting of tin (Sn) oxide, antimony (Sb), niobium (Nb) or fluorine-doped tin (Sn) oxide, indium (In) oxide, tin-doped indium (In) oxide, zinc (Zn) oxide, aluminum (Al), boron (B), gallium (Ga), hydrogen (H), indium (In), yttrium (Y), titanium (Ti), silicon (Si) or tin (Sn)-doped zinc (Zn) oxide, magnesium (Mg) oxide, cadmium (Cd) oxide, magnesium-zinc (MgZn) oxide, indium-zinc (InZn) oxide, copper-aluminum (CuAl) oxide, silver (Ag) oxide, gallium (Ga) oxide, zinc-tin oxide (ZnSnO), titanium oxide (TiO₂) and zinc-indium-tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium-titanium (SrTi) oxide and mixtures thereof, and preferably titanium oxide.

Further, the high temperature resistant substrate to be coated with the paste is a substrate for transfer as described above, and any type of substrate can be used, as long as it is calcinable at high temperature.

As the coating method, screen printing or the like may be used, but the method is not particularly limited. Any typical coating method such as doctor blade may be used.

The adhesive layer may be formed using a paste containing a thermal fusion polymer film or a thermal fusion polymer resin. Preferably, the adhesive layer may contain one or more compounds selected from the group consisting of surlyn, bynel, UV resin, epoxy and mixtures thereof as the transparent polymer adhesive layer, but is not limited thereto. In addition, the adhesive layer may be layered to have a predetermined length as much as the area of the porous layer, which is required to manufacture a dye-sensitized solar cell, and the area and thickness are not particularly limited.

The flexible transparent substrate may be one or more transparent plastic substrates selected from the group consisting of polyethylene terephthalate (PET); polyethylene naphthalate (PEN); polycarbonate (PC); polypropylene (PP); polyimide (PI); triacetylcellulose (TAC); polyethersulfone; a modified organic silicate having a 3-D network structure that is prepared by a hydrolysis and condensation reaction of an organic metal alkoxide of one or more selected from the group consisting of methyltriethoxysilane (MTES), ethyltriethoxysilane (ETES) and propyltriethoxysilane (PTES); copolymers thereof; and mixtures thereof.

Further, the step of preparing a second substrate is a step of separating the high temperature resistant substrate from the first substrate using the transfer method so as to transfer the porous layer from the first substrate to the flexible substrate, and the transfer method may be modified depending on the type of the high temperature resistant substrate. For example, if the high temperature resistant substrate is a glass substrate, a transfer method using an HF solution may be used. Further, if the high temperature resistant substrate is a ceramic substrate, the porous layer may be easily transferred to the flexible substrate by detaching the ceramic substrate from the first substrate. Furthermore, if the high temperature resistant substrate is a metal substrate, a transfer method using an acid may be used. Among them, the most preferred method is the transfer method using an HF solution.

Therefore, the step of preparing a second substrate comprises the step of immersing the first substrate in an HF solution to separate the high temperature resistant substrate from the first substrate that includes the high temperature resistant substrate, the porous layer including metal oxide nanoparticles, the adhesive layer and the flexible transparent substrate, thereby transferring the porous layer and the adhesive layer to the flexible transparent substrate. The high temperature resistant substrate may be a glass substrate.

In this regard, the transfer method using an HF solution, which has the property of melting the surface of glass substrate, may be employed in the above step of the present invention. In the above transfer method, when a TiO₂ film on the glass substrate is immersed in the HF solution, the HF solution melts the surface of the glass substrate only without damage to the surface of the plastic substrate or the adhesive layer. Thus, the TiO₂ film is detached from the glass substrate to separate them.

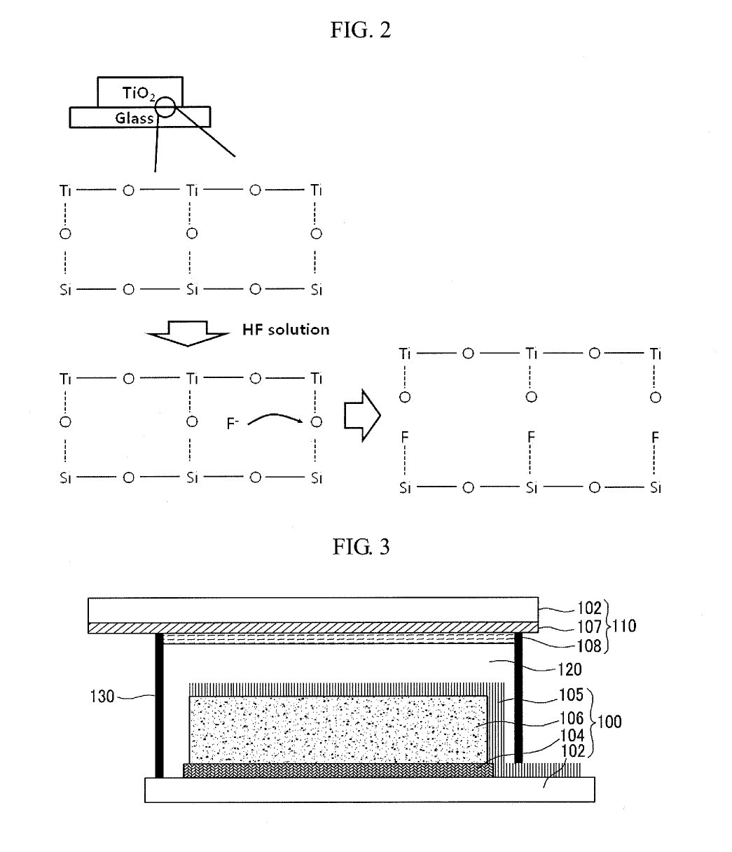

The transfer method of the present invention is performed according to FIG. 2. With reference to FIG. 2, when the second substrate is immersed in the HF solution, silicon (Si) of the high temperature resistant substrate made of glass has affinity to F⁻ of the HF solution to melt the high temperature resistant substrate, and therefore, the contact interface between the high temperature resistant substrate and the porous layer are separated. In addition, a part of the porous layer is melted by the HF solution so as to separate the interface between the high temperature resistant substrate and the porous layer contacted with the high temperature resistant substrate. During this process, the porous layer formed in the bottom of the high temperature resistant substrate is completely separated therefrom. In addition, since the adhesive layer layered on the porous layer of the second substrate is adhered to the porous layer by hot press, the separation of the porous layer from the adhesive layer can be prevented.

Further, the step of preparing a second substrate comprises a step of separating the high temperature resistant substrate by applying a physical force to the first substrate that includes the high temperature resistant substrate, the porous layer including metal oxide nanoparticles, the adhesive layer and the flexible transparent substrate, and the high temperature resistant substrate may be a ceramic substrate.

When the ceramic substrate is used as the high temperature resistant substrate, the porous layer is easily transferred to the flexible transparent substrate only by separating the high temperature resistant substrate from the first substrate that includes the high temperature resistant substrate, the porous layer including metal oxide nanoparticles, the adhesive layer and the flexible transparent substrate. In this case, the porous layer remains on the flexible substrate owing to the adhesion of the adhesive layer that is used upon the formation of the first substrate.

Furthermore, the step of preparing a second substrate comprises the steps of immersing the first substrate in an acid solution to separate the high temperature resistant substrate from the first substrate that includes the high temperature resistant substrate, the porous layer including metal oxide nanoparticles, the adhesive layer and the flexible transparent substrate, and then transferring the porous layer and the adhesive layer to the flexible transparent substrate, and the high temperature resistant substrate may be a metal substrate.

That is, when the metal substrate is used as the high temperature resistant substrate, transfer of the porous layer may be performed by immersing the first substrate in an acid solution capable of melting the metal substrate in a similar way to the method of using the HF solution. Any typical acid solution may be used as the acid solution, and a weak acid is preferred, for example, a weak acidic HCl solution.

In this regard, when the porous layer and the adhesive layer are separated from the high temperature resistant substrate, the area as much as needed for the manufacture of dye-sensitized solar cell may be only separated from the high temperature resistant substrate. Therefore, the area of the separated porous layer corresponds to that of the adhesive layer that is layered on the flexible transparent substrate, and a part of the porous layer still remains on the high temperature resistant substrate.

A volume ratio of HF and water in the HF solution may be 1:99˜100:0, and preferably 1:99 to 90:10. That is, a solution containing HF only may be used in the transfer method, if necessary. However, if the HF concentration increases, the time required to separate the high temperature resistant substrate and the porous layer including metal oxide nanoparticles can be shortened, but there is a risk in the use and storage of HF, and it may have adverse effects on the porous layer including metal oxide nanoparticles. Therefore, it is more preferable that the volume ratio of HF and water in the HF solution is 1:99 to 90:10. In one preferred example, the first substrate is immersed in the HF solution of 1 to 90% concentrations for 1100 min. When it is immersed in the HF solution, the high temperature resistant substrate is removed from the first substrate, and the porous layer and the adhesive layer are intactly transferred to the flexible transparent substrate. Finally, the second substrate, which includes flexible transparent substrate-adhesive layer-porous layer in this order, is prepared.

Further, the step of preparing a third substrate may comprise a step of forming a conductive non-metal film 105 on the top of the porous layer 103, on one side of the adhesive layer 104 and the porous layer 103, and on the top of the flexible transparent substrate 102 where the adhesive layer is not formed, as shown in (e) of FIG. 1.

Further, the conductive non-metal film formed on the top of the flexible transparent substrate may be exposed to the outside and connected to an external circuit.

Preferably, the conductive non-metal film is made to be directly formed on the top and one side of the porous layer. In addition, the conductive non-metal film is made to be directly formed on one side of the adhesive layer and on the top of flexible transparent substrate where the adhesive layer is not formed. In this regard, the conductive non-metal film is preferably designed to be connected to the external circuit upon the manufacture of a solar cell. As shown in (e)-(g) of FIG. 1, the conductive non-metal film may be contacted with the adhesive layer to be formed on the flexible transparent substrate in any direction.

The conductive non-metal film may function as a transparent electrode of the photoelectrode. The conductive film may be a porous type of photoelectrode that can retain a high level of electrical conductivity and have smooth movement of electrolyte, compared to the conventional metal films. A photoelectrode may be provided for a dye-sensitized solar cell excluding the conventional transparent conductive film (ITO, FTO, ZnO—Ga₂O₃, ZnO—Al₂O₃, SnO₂—Sb₂O₃) applied to the transparent substrate in the related art. According to the method of the present invention, the photoelectrode comprising the porous layer directly contacted on the transparent flexible substrate may be manufactured without intermediation of the conductive film, compared to a conventional photoelectrode comprising the porous layer arranged with intermediation of the conductive film.

The conductive non-metal film may be formed by sputtering, cathode arc deposition, evaporation, e-beam evaporation, chemical vapor deposition, atomic layer deposition, electrochemical deposition, spin coating, spray coating, doctor blade coating, or screen printing method.

Preferably, the components of the conductive non-metal film may be selected from the materials that have conductivity sufficient for flowing electrons formed in the dye-adsorbed porous layer 106 to an external circuit and transmitting an electric energy, chemical resistance to various chemicals in an electrolyte, and no influence on performance of the dye-sensitized solar cells.

Examples of the materials to be used for the conductive non-metal film may include one or more compounds selected from the group consisting of metals such as titanium, metal nitrides, metal oxides, carbon compounds, and polymer films, but are not limited thereto.

Further, the metal nitrides may be one or more selected from the group consisting of group IVB metal nitrides containing titanium (Ti), zirconium (Zr), and hafnium (Hf); group VB metal nitrides containing niobium (Nb), tantalum (Ta), and vanadium (V); group VIB metal nitrides containing chromium (Cr), molybdenum (Mo), and tungsten (W); aluminum nitride, gallium nitride, indium nitride, silicon nitride, germanium nitride and mixtures thereof. The metal nitrides may be preferably one or more selected from the group consisting of titanium (Ti) nitride, zirconium (Zr) nitride, hafnium nitride, niobium (Nb) nitride, tantalum (Ta) nitride, vanadium nitride, chromium (Cr) nitride, molybdenum (Mo) nitride, tungsten (W) nitride, aluminum (Al) nitride, gallium (Ga) nitride, indium (In) nitride, silicon (Si) nitride, and germanium (Ge) nitride.

The metal oxides may be one or more selected from the group consisting of tin (Sn) oxide, stibium (Sb)-, niobium (Nb)-, or fluorine-doped tin (Sn) oxide, indium (In) oxide, tin-doped indium (In) oxide, zinc (Zn) oxide, aluminum (Al)-, boron (B)-, gallium (Ga)-, hydrogen (H)-, indium (In)-, yttrium (Y)-, titanium (Ti)-, silicon (Si)- or tin (Sn)-doped zinc (Zn) oxide, magnesium (Mg) oxide, cadmium (Cd) oxide, magnesium-zinc (MgZn) oxide, indium-zinc (InZn) oxide, copper-aluminum (CuAl) oxide, silver (Ag) oxide, gallium (Ga) oxide, zinc-tin oxide (ZnSnO), titanium oxide (TiO₂), zinc-indium-tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, and mixtures thereof.

The carbon compounds may be one or more selected from the group consisting of activated carbon, graphite, carbon nanotubes, carbon black, graphene, and mixtures thereof.

The conductive polymers may be one or more selected from the group consisting of PEDOT (poly(3,4-ethylenedioxythiophene))-PSS (poly(styrenesulfonate)), polyaniline-CSA (The emeraldine salt form of polyaniline protonated with camphor sulfonic acid), pentacene, polyacetylene, P3HT (poly(3-hexylthiophene), polysiloxane carbazole, polyaniline, polyethylene oxide, poly(1-methoxy-4-(O-disperse red 1)-2,5-phenylene-vinylene), polyindole, polycarbazole, polypyridazin, polyisothianaphthalene, polyphenylene sulfide, polyvinylpyridine, polythiophene, polyfluorene, polypyridine, polypyrrole, polysulfur nitride, and copolymers thereof.

The thickness of the conductive non-metal film 105 may be determined considering smooth movement of the electrolyte which forwards electrons to the photosensitive dye. Preferably, the average thickness of the conductive non-metal film may be 1 to 1000 nm.

According to the present invention, the metal nitrides may be mixed with a small amount of oxygen or fluorine to achieve higher performances in terms of electrical, optical, or mechanical characteristics, as well as durability and environmental resistance. In this regard, the atomic ratio of O₂/(N₂+O₂), F₂/(N₂+F₂), or (O₂+F₂)/(N₂+O₂+F₂) may be preferably 0.2 or less in order to prevent degradation of characteristics due to excessive generation of oxides or fluorides.

Further, the step of adsorbing a dye may comprise the step of immersing the third substrate in a solution containing a photosensitive dye for 1 to 24 hrs to adsorb the dye to the metal oxide nanoparticles of the third substrate.

The photosensitive dye may be a dye that has band gap energy of 1.55 to 3.1 eV to absorb visible rays. For example, the photosensitive dye may include an organic-inorganic complex dye containing metal or metal composite, an organic dye, or mixtures thereof. Examples of the organic-inorganic complex dye may be an organic-inorganic complex dye containing an element selected from the group consisting of aluminum (Al), platinum (Pt), palladium (Pd), europium (Eu), lead (Pb), iridium (Ir), ruthenium (Ru), and complexes thereof.

Meanwhile, according to another embodiment of the present invention, a flexible photoelectrode manufactured by the above method is provided. Preferably, the present invention provides a flexible photoelectrode for a dye-sensitized solar cell, comprising the flexible transparent substrate 102, the adhesive layer 104 formed on one side of the flexible transparent substrate, the porous layer 106 including dye-adsorbed metal oxide nanoparticles that is formed on the adhesive layer, and the conductive non-metal film 105 that is directly formed on the top and the side of the porous layer and directly formed on the side of the adhesive layer and on the top of the flexible transparent substrate where the adhesive layer is not formed.

The flexible substrate may be one or more plastic substrates selected from the group consisting of polyethylene terephthalate; polyethylenenaphthalate; polycarbonate; polypropylene; polyimide; a modified organic silicate having a 3-D network structure that is prepared by a hydrolysis and condensation reaction of an organic metal alkoxide of one or more selected from the group consisting of triacetylcellulose, polyethersulfone, methyltriethoxysilane, ethyltriethoxysilane, and propyltriethoxysilane; copolymers thereof; and mixtures thereof. In addition, the thickness of the flexible transparent substrate is not particularly limited, but preferably 50 to 500 um.

The adhesive layer may be formed using a paste containing a thermal fusion polymer film or a thermal fusion polymer resin.

Further, the porous layer may include one or more metal oxide nanoparticles selected from the group consisting of tin (Sn) oxide, stibium (Sb)-, niobium (Nb)-, or fluorine-doped tin (Sn) oxide, indium (In) oxide, tin-doped indium (In) oxide, zinc (Zn) oxide, aluminum (Al)-, boron (B)-, gallium (Ga)-, hydrogen (H)-, indium (In)-, yttrium (Y)-, titanium (Ti)-, silicon (Si)- or tin (Sn)-doped zinc (Zn) oxide, magnesium (Mg) oxide, cadmium (Cd) oxide, magnesium-zinc (MgZn) oxide, indium-zinc (InZn) oxide, copper-aluminum (CuAl) oxide, silver (Ag) oxide, gallium (Ga) oxide, zinc-tin oxide (ZnSnO), titanium oxide (TiO₂), zinc-indium-tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium-titanium (SrTi) oxide and mixtures thereof. In addition, the thickness of the porous layer is not particularly limited, but preferably 1 to 40 um.

The conductive non-metal film may include a metal electrode, metal nitride, metal oxide, carbon compound, or conductive polymer having an average thickness of 1 to 1000 nm. In this regard, the types of metal nitrides, metal oxides, carbon compounds, or conductive polymers are the same as described above.

Meanwhile, according to still another embodiment, the present invention provides a flexible dye-sensitized solar cell, comprising the flexible photoelectrode, a counter electrode disposed to face the photoelectrode with a predetermined space, and an electrolyte charged between the photoelectrode and the counter electrode.

FIG. 3 is a schematic view of a cross section of the flexible dye-sensitized solar cell according to one embodiment of the present invention. In this regard, the structure of the flexible dye-sensitized solar cell of FIG. 3 is for illustrative purposes only, and the invention is not intended to be limited thereto.

As shown in FIG. 3, the dye-sensitized solar cell according to one embodiment of the present invention comprises the photoelectrode 100 comprising the flexible transparent substrate 102, the adhesive layer 104, the porous layer 106 including dye-adsorbed metal oxide nanoparticles, and the conductive non-metal film 105, the counter electrode 110 disposed to face the photoelectrode 100 with a predetermined space, and the electrolyte 120 filled between the two electrodes, and a polymer adhesive 130 sealing them.

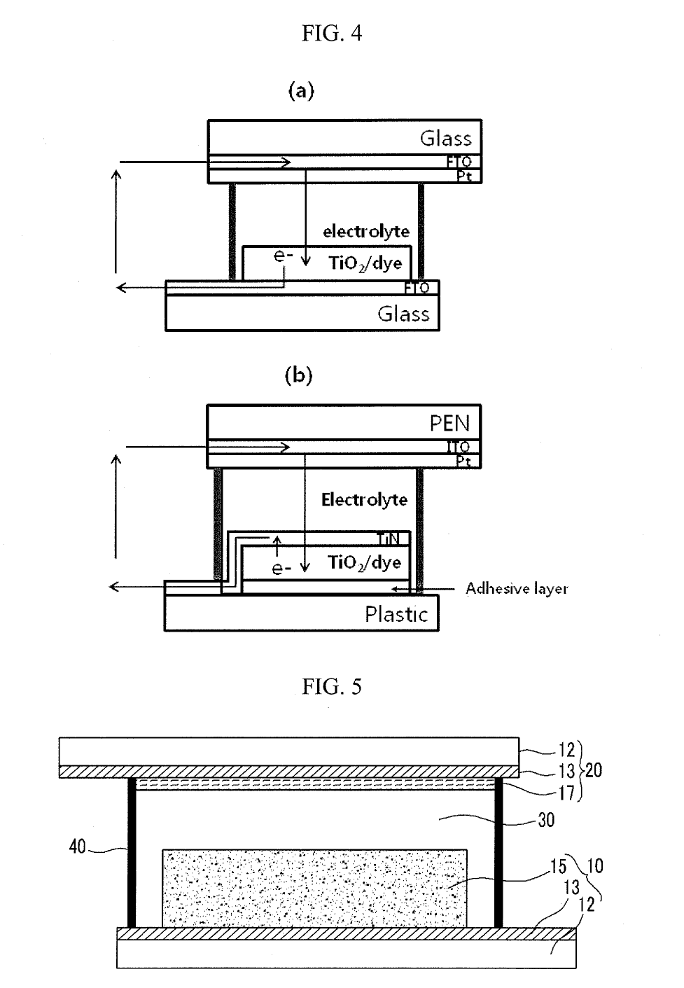

The dye-sensitized solar cell having the structure may form a semiconductor electrode having excellent energy conversion efficiency on the flexible transparent substrate by transferring the porous layer formed on the high temperature resistant substrate to the flexible transparent substrate according to the aforementioned transfer method of the present invention. In the present invention, since electrons moves according to the operating principle of a solar cell using a back electrode in (b) of FIG. 4, not according to the general operating principle of a dye-sensitized solar cell depicted in (a) of FIG. 4, the solar cell of the present invention is able to show more excellent photoelectric conversion efficiency, compared to the conventional solar cells.

In this regard, the counter electrode 11 may comprise the flexible transparent substrate 102, and a conductive film 107 and a catalyst layer 108 that are formed on the flexible transparent substrate. The catalyst layer means a nanoparticle metal film formed using Pt or the like in order to constitute the counter electrode. The catalyst layer may comprise one or more selected from the group consisting of platinum (pt), activated carbon, graphite, carbon nanotubes, carbon black, a p-type semiconductor, PEDOT (poly(3,4-ethylenedioxythiophene))-PSS (poly(styrenesulfonate)), polyaniline-CSA, pentacene, polyacetylene, P3HT (poly(3-hexylthiophene), polysiloxane carbazole, polyaniline, polyethylene oxide, poly(1-methoxy-4-(O-disperse red 1)-2,5-phenylene-vinylene), polyindole, polycarbazole, polypyridazin, polyisothianaphthalene, polyphenylene sulfide, polyvinylpyridine, polythiophene, polyfluorene, polypyridine, polypyrrole, polysulfur nitride, and derivatives thereof and copolymers thereof or complexes thereof and mixtures thereof.

The conductive film 107 means a transparent conductive oxide (TCO) that may be formed on the flexible transparent substrate 102, and it may be SnO₂:F or ITO. However, the conductive film is not limited thereto, and a typical conductive film well known in the art may be formed on the flexible transparent substrate.

In addition, the flexible transparent substrate 102 constituting the counter electrode 110 may be a transparent plastic substrate, which is identical to that used in the preparation of the photoelectrode.

In the present invention, the thickness of the flexible transparent substrate, the conductive film and the catalyst layer of the counter electrode is not particularly limited.

The electrolyte 120, although depicted in FIG. 2 as if it is simply filled, for convenience, is practically uniformly dispersed within the metal oxide nanoparticle layer of the porous layer 106 between the photoelectrode 100 and the counter electrode 110.

The electrolyte comprises a redox derivative that functions to forward electrons from the counter electrode to the photosensitive dye by oxidation-reduction reactions, and the redox derivative is not particularly limited as long as it is can be used in the typical dye-sensitized solar cells. Specifically, the redox derivative is preferably one or more selected from the group consisting of electrolytes including iodine (I), bromine (Br), cobalt (Co), thiocyanate (SCN—), and selenocyanate (SeCn—). In addition, the electrolyte may comprise one or more polymers selected from the group consisting of polyvinylidenefluoride-co-polyhexafluoropropylene, polyacrylonitrile, polyethylene oxide, and polyalkylacrylate. In addition, the electrolyte may be a polymer gel electrolyte comprising one or more inorganic particles selected from the group consisting of silica and TiO₂ nanoparticles.

In addition, the solar cell may further comprise an adhesive that is a thermal fusion polymer film or paste in order to seal the semiconductor electrode and the counter electrode. A typical material may be used as the adhesive, and the type is not particularly limited.

### EXAMPLES

Hereinafter, Examples of the present invention will be described. However, these Examples are for illustrative purposes only, and the scope of the invention is not intended to be limited by these Examples.

### Example 1

### Preparation of Photoelectrode

As a substrate of photoelectrode, a glass substrate (thickness: 1 mm) was prepared. Afterward, a metal oxide nanoparticle paste containing 18.5% by weight of titanium oxide nanoparticles (average particle diameter: 20 nm), 0.05% by weight of binder polymer (ethyl cellulose), and a residual amount of solvent (Terpineol) was applied to the glass substrate using a doctor blade. Then, the substrate was heat-treated at 500° C. for 30 min so as to form a porous layer (thickness: 6.1 μm) including metal oxide nanoparticles.

Subsequently, a transparent adhesive layer (surlyn, bynel, thickness: 25 μm) was layered on the porous layer including titanium oxide nanoparticles, and a transparent plastic substrate (material: PEN, thickness: 200 μm) was layered thereon, followed by hot press using a press machine (top plate/bottom plate: 80° C./100° C., pressure: 1 bar). The porous layer formed on the glass substrate, the transparent adhesive layer (surlyn, bynel) and the transparent plastic substrate were attached to each other by this process, and then the substrate was immersed in a 5% HF solution for 20 sec to detach the glass substrate, thereby preparing a substrate that includes the porous layer including titanium oxide nanoparticles, the adhesive layer and the transparent plastic substrate in this order.

Thereafter, a TiN conductive ceramic film was deposited to a thickness of 100 nm on the top of the substrate where the adhesive layer was not formed, on the top of the porous layer, and on the right side of the adhesive layer and the porous layer by magnetron sputtering. While maintaining base pressure of the chamber at 5.0×10⁻⁷ Torr or less, pure Ar gas and N₂ gas were mixed to adjust the volume ratio of N₂/(N₂+Ar). An experiment was performed under Ar gas atmosphere with the addition of 3 vol % of N₂ at a process pressure of 1 mTorr, a substrate temperature of room temperature, a target power of 80 W, and a fixed distance between the target and the substrate of 6.6 cm.

Subsequently, the substrate was immersed in an ethanol solution containing 0.3 mM [Ru(4,4′-dicarboxy-2,2′-bipyridine)₂(NCS)₂] as a photosensitive dye for 12 hrs, and thus the photosensitive dye was adsorbed onto the surface of the porous layer including metal oxide nanoparticles so as to prepare the photoelectrode.

(Preparation of Counter Electrode)

As a substrate for counter electrode, a conductive plastic substrate (Peccell Technologies, Inc. material: PEN, thickness: 188 μm, 5 Ω/sq) coated with Pt/Ti alloy to a thickness of 30 nm was used.

(Injection of Electrolyte and Sealing)

Acetonitrile electrolyte containing PMII (1-methyl-3-propylimidazolium iodide, 0.7 M) and I₂ (0.03 M) was injected between the above-prepared photoelectrode and counter electrode, and sealed using a typical polymer resin to prepare a dye-sensitized solar cell having the structure of FIG. 3.

### Comparative Example 1

### Preparation of Photoelectrode

As a substrate of photoelectrode, a conductive plastic substrate (Peccell Technologies, Inc, material: PEN/ITO, thickness: 200 μm, 15 Ω/sq, substrate including 12 and 13 of FIG. 5) was prepared. Afterward, a metal oxide nanoparticle paste containing 15% by weight of titanium oxide nanoparticles (average particle diameter: 20 nm) and 85% by weight of solvent (Ethanol) was applied to the glass substrate using a doctor blade. Then, the substrate was heat-treated at 150° C. for 30 min so as to form a porous layer including metal oxide nanoparticles (thickness: 6.3 μm, 15 of FIG. 5). In Comparative Example 1, the thickness cannot be increased due to the weak bonding strength between TiO₂ because of using a paste without a binder at a low temperature.

Subsequently, the substrate was immersed in an ethanol solution containing 0.5 mM [Ru(4,4′-dicarboxy-2,2′-bipyridine)₂(NCS)₂] as a photosensitive dye for 12 hrs, and thus the photosensitive dye was adsorbed onto the surface of the porous layer so as to prepare the photoelectrode (10 of FIG. 5).

(Preparation of Counter Electrode)

As a substrate for counter electrode, a conductive plastic substrate (Peccell Technologies, Inc, material: PEN, thickness: 188 μm, 5 Ω/sq) coated with Pt/Ti alloy to a thickness of 30 nm was used (counter electrode 20 composed of 12, 13, and 17 of FIG. 5).

(Injection of Electrolyte and Sealing)

Acetonitrile electrolyte containing PMII (1-methyl-3-propylimidazolium iodide, 0.7 M) and I₂ (0.03 M) was injected between the above-prepared photoelectrode and counter electrode, and sealed using a typical polymer resin to prepare a dye-sensitized solar cell having the structure of FIG. 5.

### Experimental Example 1

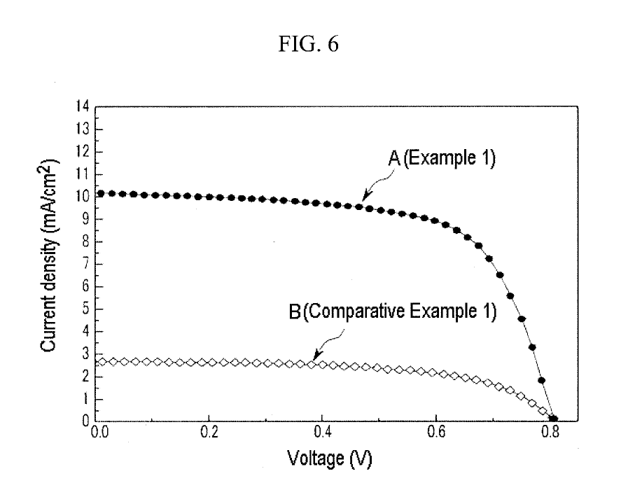

For each dye-sensitized solar cell manufactured in Example 1 and Comparative Example 1, open circuit voltage, photocurrent density, energy conversion efficiency, and fill factor were measured as follows, and the results are summarized in the following Table 1. In addition, the current-voltage curves of the solar cells manufactured in Example 1 and Comparative Example 1, which were obtained under AM 1.5 G and 1 Sun condition, are depicted in FIG. 6

(1) Open Circuit Voltage (V) and Photocurrent Density (mA/cm²):

Open circuit voltage and photocurrent density were measured using Keithley SMU2400.

(2) Energy Conversion Efficiency (%) and Fill Factor (%):

Energy conversion efficiency was measured using 1.5 AM 100 mW/cm² solar simulator (consisting of Xe lamp [1600 W, YAMASHITA DENSO], AM1.5 filter, and Keithley SMU2400), and fill factor was calculated using the obtained conversion efficiency and the following Equation.

Fill factor(%)=(J×V)ₘₐₓ/J_{sc}×V_{oc}×100 [Equation]
wherein J is a y-axis value of a conversion efficiency curve, V is an x-axis value of a conversion efficiency curve, and Jₛₓ and V_{oc} are intercepts of each axis.

TABLE 1

| | | | | | | TiO₂ |
|---|---|---|---|---|---|---|
| | J_{sc} | V_{oc} | FF | Efficiency | Area | thickness |
| | (mA/cm²) | (V) | (%) | (%) | (cm²) | (μm) |
| Example 1 | 10.16 | 0.784 | 65.9 | 5.24 | 0.215 | 6.1 |
| Comparative | 2.56 | 0.803 | 60.9 | 1.25 | 0.343 | 6.3 |
| Example 1 | | | | | | |

As shown in Table 1 and FIG. 6, the dye-sensitized solar cell of Example 1, which comprises an electrode prepared by transferring a high temperature-calcined film to a flexible substrate, showed higher efficiency than the plastic dye-sensitized solar cell of Comparative Example 1 that was prepared by low temperature calcination.

Therefore, the solar cell of the present invention comprises a porous layer having excellent photoelectric conversion efficiency which is formed on the flexible plastic substrate by high temperature calcination, excluding the expensive transparent conductive film, thereby being applied to various fields such as electronics requiring flexibility or power generation.

### EFFECT OF THE INVENTION

According to the present invention, a porous layer including metal oxide nanoparticles that is formed on a high temperature resistant substrate by high temperature calcination is transferred to a transparent plastic substrate by a transfer method using an HF solution, thereby manufacturing a flexible photoelectrode comprising the porous layer including metal oxide nanoparticles and a conductive non-metal film on the transparent plastic substrate. Therefore, the present invention is able to provide a porous type of photoelectrode that can retain a high level of electrical conductivity and have smooth movement of electrolyte, compared to those using thin films, and also have excellent stability because of using a film calcined at high temperature, which cannot be used in the conventional plastic films. In the present invention, an expensive transparent conductive film can be also excluded, thereby providing a dye-sensitized solar cell comprising a photoelectrode with advanced transmittance, which includes a flexible transparent substrate made of using a plastic substrate with high efficiency.

What is claimed is:

1. A method for manufacturing a flexible photoelectrode, comprising the steps of:
(a) preparing a first substrate that includes a high temperature resistant substrate, a porous layer including metal oxide nanoparticles, an adhesive layer and a flexible transparent substrate;
(b) separating the high temperature resistant substrate from the first substrate by a transfer method so as to prepare a second substrate that includes the flexible transparent substrate, and the adhesive layer and the porous layer disposed on the flexible transparent substrate;
(c) forming a conductive non-metal film on the side of the porous layer and the adhesive layer and on the top of flexible transparent substrate of the second substrate so as to prepare a third substrate including the flexible transparent substrate, and the adhesive layer, the porous layer and the conductive non-metal film that are formed on the flexible transparent substrate; and
(d) adsorbing a dye on the surface of the porous layer of the third substrate.

2. The method according to claim 1, wherein the step of preparing a first substrate comprises the steps of:
forming the porous layer including metal oxide nanoparticles on one side of the high temperature resistant substrate; and
sequentially disposing the adhesive layer and the flexible transparent substrate on the porous layer including metal oxide nanoparticles, followed by hot press of the substrate.

3. The method according to claim 2, wherein the porous layer is formed by coating one side of the high temperature resistant substrate with a paste containing metal oxide nanoparticles, a binder and a solvent and by heat-treatment at a temperature of 450 to 500° C. for 1˜2 hrs.

4. The method according to claim 1, wherein the high temperature resistant substrate includes a glass substrate, a ceramic substrate, or a metal substrate.

5. The method according to claim 1, wherein the step of preparing a second substrate comprises the steps of immersing the first substrate in an HF solution to separate the high temperature resistant substrate from the first substrate including the high temperature resistant substrate, the porous layer including metal oxide nanoparticles, the adhesive layer and the flexible transparent substrate; and transferring the porous layer and the adhesive layer to the flexible substrate, and the high temperature resistant substrate is a glass substrate.

6. The method according to claim 5, wherein a volume ratio of HF and water in the HF solution is 1:99˜100:0.

7. The method according to claim 1, wherein the step of preparing a second substrate comprises the step of separating the high temperature resistant substrate by applying a physical force to the first substrate that includes the high temperature resistant substrate, the porous layer including metal oxide nanoparticles, the adhesive layer and the flexible transparent substrate, and the high temperature resistant substrate is a ceramic substrate.

8. The method according to claim 1, wherein the step of preparing a second substrate comprises the steps of immersing the first substrate in an acid solution to separate the high temperature resistant substrate from the first substrate that includes the high temperature resistant substrate, the porous layer including metal oxide nanoparticles, the adhesive layer and the flexible transparent substrate; and then transferring the porous layer and the adhesive layer to the flexible transparent substrate, and the high temperature resistant substrate is a metal substrate.

9. The method according to claim 1, wherein the step of preparing a third substrate comprises the step of forming a conductive non-metal film on the top of the porous layer, on one side of the adhesive layer and the porous layer, and on the top of the flexible transparent substrate where the adhesive layer is not formed.

10. The method according to claim 1, wherein the conductive non-metal film is formed by sputtering, cathode are deposition, evaporation, e-beam evaporation, chemical vapor deposition, atomic layer deposition, electrochemical deposition, spin coating, spray coating, doctor blade coating, or screen printing method.

11. The method according to claim 1, wherein the adhesive layer is formed using a paste containing a thermal fusion polymer film or a thermal fusion polymer resin.

12. The method according to claim 1, wherein the flexible transparent substrate is one or more plastic substrates selected from the group consisting of polyethylene terephthalate; polyethylenenaphthalate; polycarbonate; polypropylene; polyimide; a modified organic silicate having a 3-D network structure that is prepared by a hydrolysis and condensation reaction of an organic metal alkoxide of one or more selected from the group consisting of triacetylcellulose, polyethersulfone, methyltriethoxysilane, ethyltriethoxysilane, and propyltriethoxysilane; copolymers thereof; and mixtures thereof.

13. The method according to claim 1, wherein the step of adsorbing a dye comprises the step of immersing the third substrate in a solution containing a photosensitive dye for 1 to 24 hrs to adsorb the dye to the metal oxide nanoparticles of the third substrate.

14. A flexible photoelectrode for a dye-sensitized solar cell that is manufactured by the method of any one of claim 1, comprising
a flexible transparent substrate,
an adhesive layer that is formed on one side of the flexible transparent substrate,
a porous layer including dye-adsorbed metal oxide nanoparticles that is formed on the adhesive layer, and
a conductive non-metal film that is directly formed on the top and the side of the porous layer and directly formed on the side of the adhesive layer and on the top of the flexible transparent substrate where the adhesive layer is not formed.

15. The flexible photoelectrode for a dye-sensitized solar cell according to claim 14, wherein the conductive non-metal film include a metal electrode, metal nitride, metal oxide, carbon compound, or conductive polymer having an average thickness of 1 to 1000 nm.

16. The flexible photoelectrode for a dye-sensitized solar cell according to claim 17, wherein the metal nitride is one or more selected from the group consisting of group IVB metal nitrides, group VB metal nitrides, group VIB metal nitrides, aluminum nitride, gallium nitride, indium nitride, silicon nitride, germanium nitride and mixtures thereof.

17. The flexible photoelectrode for a dye-sensitized solar cell according to claim 17, wherein the metal oxide is one or more selected from the group consisting of tin (Sn) oxide, stibium (Sb)-, niobium (Nb)-, or fluorine-doped tin (Sn) oxide, indium (In) oxide, tin-doped indium (In) oxide, zinc (Zn) oxide, aluminum (Al)-, boron (B)-, gallium (Ga)-, hydrogen (H)-, indium (In)-, yttrium (Y)-, titanium (Ti)-, silicon (Si)- or tin (Sn)-doped zinc (Zn) oxide, magnesium (Mg) oxide, cadmium (Cd) oxide, magnesium-zinc (MgZn) oxide, indium-zinc (InZn) oxide, copper-aluminum (CuAl) oxide, silver (Ag) oxide, gallium (Ga) oxide, zinc-tin oxide (ZnSnO), titanium oxide (TiO₂), zinc-indium-tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, and mixtures thereof.

18. The flexible photoelectrode for a dye-sensitized solar cell according to claim 17, wherein the carbon compound is one or more selected from the group consisting of activated carbon, graphite, carbon nanotubes, carbon black, graphene, and mixtures thereof,
wherein the conductive polymer is one or more selected from the group consisting of poly(3,4-ethylenedioxythiophene)-poly(styrenesulfonate), polyaniline-CSA, pentacene, polyacetylene, poly(3-hexylthiophene, polysiloxane carbazole, polyaniline, polyethylene oxide, poly(1-methoxy-4-(O-disperse red 1)-2,5-phenylene-vinylene), polyindole, polycarbazole, polypyridazin, polyisothianaphthalene, polyphenylene sulfide, polyvinylpyridine, polythiophene, polyfluorene, polypyridine, polypyrrole, polysulfur nitride, and copolymers thereof.

19. The flexible photoelectrode for a dye-sensitized solar cell according to claim 14, wherein the porous layer comprises one or more metal oxide nanoparticles selected from the group consisting of tin (Sn) oxide, stibium (Sb)-, niobium (Nb)-, or fluorine-doped tin (Sn) oxide, indium (In) oxide, tin-doped indium (In) oxide, zinc (Zn) oxide, aluminum (Al)-, boron (B)-, gallium (Ga)-, hydrogen (H)-, indium (In)-, yttrium (Y)-, titanium (Ti)-, silicon (Si)- or tin (Sn)-doped zinc (Zn) oxide, magnesium (Mg) oxide, cadmium (Cd) oxide, magnesium-zinc (MgZn) oxide, indium-zinc (InZn) oxide, copper-aluminum (CuAl) oxide, silver (Ag) oxide, gallium (Ga) oxide, zinc-tin oxide (ZnSnO), titanium oxide (TiO₂), zinc-indium-tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, titanium (Ti) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium-titanium (SrTi) oxide and mixtures thereof.

20. A flexible dye-sensitized solar cell comprising:
the flexible photoelectrode according to any one of claim 14,
a counter electrode disposed to face the photoelectrode with a predetermined space, and
an electrolyte charged between the photoelectrode and the counter electrode.
